(19) United States
(12) Patent Application Publication
(10) Pub. No.: US 2008/0064186 A1
(43) Pub. Date: Mar. 13, 2008

(54) Manufacturing method of semiconductor element

(75) Inventor: Yoshihisa Imori, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/898,146

(22) Filed: Sep. 10, 2007

(30) Foreign Application Priority Data
Sep. 13, 2006 (JP) P2006-248052

(51) Int. Cl. H01L 21/78

(52) U.S. Cl. 438/462; 257/E21.599

(57) ABSTRACT

A semiconductor wafer includes plural element regions and a dicing region provided to partition off these element regions. The element region and the dicing region have a laminated film containing a low dielectric constant insulating film. In dicing the semiconductor wafer, a laser beam whose peak energy Y (W) and irradiation time X (ns/μm) per unit irradiation length satisfy a condition of Y≧53.3Ln(X)+576 is irradiated along the dicing region to cut at least the low dielectric constant film of the laminated film.

### CROSS-REFERENCE TO RELATED APPLICATIONS

This application is based upon and claims the benefit of priority from the prior Japanese Patent Application No. 2006-248052, filed on Sep. 13, 2006; the entire contents of which are incorporated herein by reference.

### BACKGROUND OF THE INVENTION

1. Field of the Invention

The present invention relates to a manufacturing method of a semiconductor element.

2. Description of the Related Art

A manufacturing process of a semiconductor device is broadly divided into a step of partitioning a semiconductor wafer into plural element regions by dicing lines in a grid pattern and forming integrated circuits in these respective element regions, a step of cutting the semiconductor wafer along the dicing lines to section the respective element regions as semiconductor elements (semiconductor chips), and a step of individually packaging these semiconductor elements. Blade dicing in which generally the semiconductor wafer is mechanically cut using a diamond blade is applied to the cutting step of the semiconductor wafer.

To cope with the miniaturization and speeding up of the semiconductor element, the application of a low dielectric constant insulating film (Low-k film) which is effective in suppressing a wiring delay (RC delay) (particularly suppressing a delay due to a reduction in a parasitic capacitance C of a wiring) to the semiconductor element is under way. As constituent materials of the Low-k film, for example, fluorine-doped silicon oxide (SiOF), carbon-doped silicon oxide (SiOC), organic silica, porous bodies thereof, and so on are used. When the semiconductor wafer using the Low-k film as an interlayer insulating film is cut by blade dicing, there is a problem that film peeling and cracking tend to occur due to brittleness and low adhesiveness of the Low-k film.

A proposal that, prior to the blade dicing of the semiconductor wafer having the Low-k film, a laser beam is irradiated along the dicing lines which partition off respective element regions to cut the Low-k film and cut not only the Low-k film but also the semiconductor wafer by the laser beam is made (see JP-A 2005-074485 (KOKAI), JP-A 2005-252196 (KOKAI)). Laser dicing is effective in cutting the Low-k film. However, in addition to the Low-k film, a laminated film (multilayer film) including a SiOₓ film, a SiNₓ film, and so on are formed on the semiconductor wafer, so that film peeling caused by a difference in degree of machining by the laser beam among respective films becomes a problem.

When the laminated film including the Low-k film, the SiOₓ film, the SiNₓ film, and soon is machined by the laser beam, a difference in machining by the laser beam occurs since optical absorptances of the respective films differ. For example, even if the respective films each in a single layer state are irradiated and machined by a laser beam of the same condition, some films are machined linearly along the laser beam, and some films are machined partially. If a film difficult to machine is placed on the upper side when dicing machining is performed by irradiating the laser beam to a laminated film having plural kinds of films, a film easy to machine inside the laminated film causes ablation earlier by the laser beam, resulting in peeling of the upper side film by internal explosion.

It is conceivable that when the laminated film is laser-diced, the inside film causes ablation before the upper side film is machined, and film machining progresses while the upper side film is destroyed by vapor pressure increased in the inside. In the laser dicing which goes through the above process, film peeling progresses to the inside between layers depending on the strength of the film itself and interface adhesion strength. The Low-k film has low film strength and adhesion strength as described above, so that it causes film peeling from inside the laminated film due to a difference in optical characteristic among respective films of the laminated film.

### SUMMARY OF THE INVENTION

A manufacturing method of a semiconductor element according to an aspect of the present invention comprises: irradiating a laser beam to a semiconductor wafer, which includes plural element regions having a laminated film containing a low dielectric constant insulating film and a dicing region provided to partition off the plural element regions and having the laminated film, along the dicing region to cut at least the low dielectric constant insulating film of the laminated film, the laser beam being irradiated under a condition that a peak energy Y (W) and an irradiation time X (ns/μm) per unit irradiation length of the laser beam satisfy an expression:

Y≦53.3Ln(X)+576;

and fabricating a semiconductor element by cutting the semiconductor wafer along the dicing region to section the plural element regions.

A manufacturing method of a semiconductor element according to another aspect of the present invention comprises: irradiating a laser beam to a semiconductor wafer, which includes plural element regions having a laminated film containing a low dielectric constant insulating film and a dicing region provided to partition off the plural element regions and having the laminated film, along the dicing region to cut at least the low dielectric constant insulating film of the laminated film, the laser beam being irradiated under a condition that a peak energy Y (W) and an irradiation time X (ns/μm) per unit irradiation length of the laser beam satisfy an expression:

−60.3Ln(X)+352≦Y≦53.3Ln(X)+576;

and fabricating a semiconductor element by cutting the semiconductor wafer along the dicing region to section the plural element regions.

### BRIEF DESCRIPTION OF THE DRAWINGS

FIG. 1 is a plan view showing a semiconductor wafer applied to a manufacturing process of a semiconductor element according to a first embodiment of the present invention.

FIG. 2 is a plan view showing part of the semiconductor wafer shown in FIG. 1 in a magnified form.

FIG. 3 is a sectional view taken along the line A-A in FIG. 2.

FIG. 4 is a sectional view showing an example of a laminated film applied to the semiconductor wafer shown in FIG. 1.

FIG. 5 is a view showing the constitution of a laser device used in embodiments of the present invention.

FIG. 6 is a photograph showing the machined state of a SiNₓ film (single layer) by a laser beam in a magnified form.

FIG. 7 is a photograph showing the machined state of a PAr-based low dielectric constant insulating film (single layer) by the laser beam in a magnified form.

FIG. 8 is a photograph showing the machined state of a SiOC-based low dielectric constant insulating film (single layer) by the laser beam in a magnified form.

FIG. 9 is a photograph showing the machined state of a TEOS film (single layer) by the laser beam in a magnified form.

FIG. 10 is a photograph showing the machined state of a FSG film (single layer) by the laser beam in a magnified form.

FIG. 11 is a graph showing machinability based on an irradiation time X per unit length and a peak energy Y of the laser beam when the laminated film is laser-machined.

FIG. 12 is a photograph showing the outside appearance when the laminated film is laser-machined under the condition of a point A in FIG. 11 in a magnified form.

FIG. 13 is a photograph showing the state of the inside of the laminated film in FIG. 12 in a magnified form.

FIG. 14 is a photograph showing the outside appearance when the laminated film is laser-machined under the condition of a point B in FIG. 11 in a magnified form.

FIG. 15 is a photograph showing the outside appearance when the laminated film is laser-machined under the condition of a point C in FIG. 11 in a magnified form.

FIG. 16 is a photograph showing the state of the inside of the laminated film when the laminated film is laser-machined under the condition of a point E in FIG. 11 in a magnified form.

FIG. 17 is a TEM photograph showing the observation result of a heat influence when the laminated film is laser-machined under the condition of the point C in FIG. 11.

FIG. 18 is a graph showing the relations between laser energy and line width of various films.

FIG. 19 is a plan view showing part of a semiconductor wafer applied to a manufacturing process of a semiconductor element according to a second embodiment of the present invention in a magnified form.

FIG. 20 is a sectional view taken along the line A-A in FIG. 19.

### DETAILED DESCRIPTION

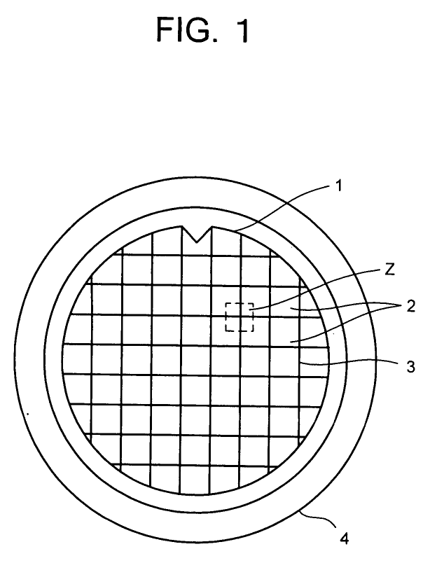

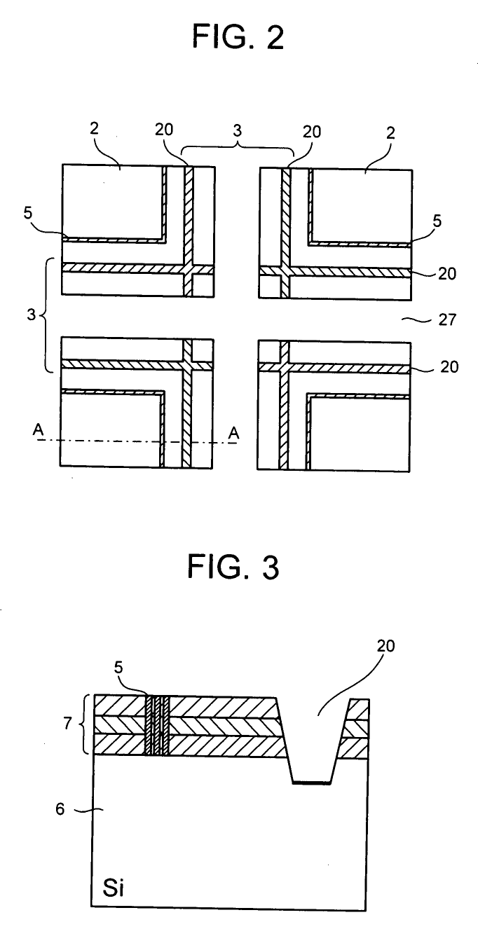

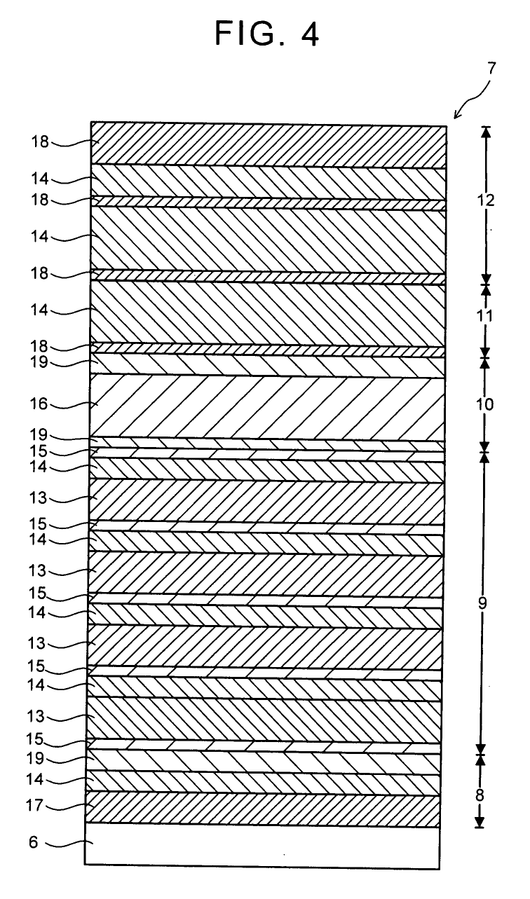

A mode for carrying out the present invention will be described below with reference to the drawings. FIG. 1 to FIG. 4 show a manufacturing process of a semiconductor element according to a first embodiment of the present invention. FIG. 1 is a plan view schematically showing the constitution of a semiconductor wafer, FIG. 2 is a plan view showing a part (region Z surrounded by a square) of the semiconductor wafer shown in FIG. 1 in a magnified form, FIG. 3 is a sectional view taken along the line A-A in FIG. 2, and FIG. 4 is a sectional view showing an example of a laminated film formed on the surface side of the semiconductor wafer shown in FIG. 1.

A semiconductor wafer 1 shown in FIG. 1, FIG. 2, and FIG. 3 includes plural element regions 2, 2 . . . and dicing regions (dicing lines) 3, 3 . . . provided in a grid pattern so as to partition off these element regions 2. Numeral 4 in FIG. 1 denotes a ring frame. As shown in FIG; 2 and FIG. 3, the element region 2 is surrounded by a chip ring 5, and an element structure such as a transistor, various circuits and wirings, and so on are formed in the chip ring 5. Each element region 2 constitutes a semiconductor element.

As shown in FIG. 2, FIG. 3, and FIG. 4, the element region 2 has a laminated film 7 formed on the surface side (element forming side) of a Si substrate 6 as a semiconductor substrate. The laminated film 7 constitutes a multilayer wiring film, a protective film, and the like. The laminated film 7 has a low dielectric constant insulating film (Low-k film) as an interlayer insulating film of the multilayer wiring film. The dicing region 3 is the same as the element region 2 in terms of a cross section structure and has the Si substrate 6 and the laminated film 7. For example, as shown in FIG. 4, the laminated film 7 has a local layer 8, an intermediate layer 9, a semiglobal layer, 10, a global layer 11, and a passivation layer 12 formed in order on the Si substrate 6.

The intermediate layer 9 has a film structure of a four-layer structure of a low dielectric constant insulating film 13, a SiOₓ film 14 such as a TEOS film, and a SiCN film 15. The intermediate layer 9 has a Cu wiring not shown, and the low dielectric constant insulating film 13 functions as an interlayer insulating film of the Cu wiring. The local layer 8, the semiglobal layer 10, the global layer 11, and the passivation layer 12 are constituted of the SiOₓ film 14 such as the TEOS film, a fluorine-doped silica glass (FSG) film 16, a non-doped silica glass (NSG) film 17, a SiNₓ film 18, a Si film 19 using a SiH₄ film, and the like.

A low dielectric constant material having a relative dielectric constant (k value) of 3.3 or less is used for the low dielectric constant insulating film 13. As examples of the low dielectric constant insulating film 13, a fluorine-doped silicon oxide film (SiOF film), a carbon-doped silicon oxide film (SiOC film), an organic-silica film, a HSQ (hydrogen silsesquioxane) film, a MSQ (methyl silsesquioxane) film, a BCB (benzocyclobutene) film, a PAE (polyarylether) film, a PTFE (polytetrafluoroethylene) film, and further porous films thereof are shown. The low dielectric constant insulating film 13 has a low adhesion strength.

In dicing machining of the semiconductor wafer 1 having the laminated film 7, first, a trench 20 is formed by irradiating a laser beam to the laminated film 7 of the dicing region 3 to remove part of the laminated film 7. The trench 20 is a laser-machined trench and formed in a portion of the laminated film 7 irradiated with the laser beam. The laser-machined trench 20 is formed so as to cut at least the low dielectric constant insulating film 13 in the laminated film 7. More specifically, the laser beam is irradiated to a portion (dicing region 3) corresponding to the outside of the element region (active area) 2 along an outer periphery of the chip ring 5. Thus, the laser-machined trench 20 which cuts the laminated film 7 is formed. The laser-machined trench 20 is formed to surround the entire outer periphery of the element region 2 along the outer periphery of the chip ring 5.

It is desirable that the laser-machined trench 20 be machined to a depth at which the Si substrate 6 is exposed, for example, a depth of 1 μm or more. Namely, it is desirable that a bottom surface of the laser-machined trench 20 be constituted of the Si substrate 6. Thus, the laminated film 7 can be more completely cut by the laser-machined trench 20. It is desirable that the laser beam be irradiated such that part of the Si substrate 6 is machined in forming the laser-machined trench 20 with good reproducibility. The width of the laser-machined trench 20 is desirably 3 μm or more on the Si substrate 6. If the width of the laser-machined trench 20 is too narrow, the cut state of the laminated film 7 including the low dielectric constant insulating film 13 may become incomplete.

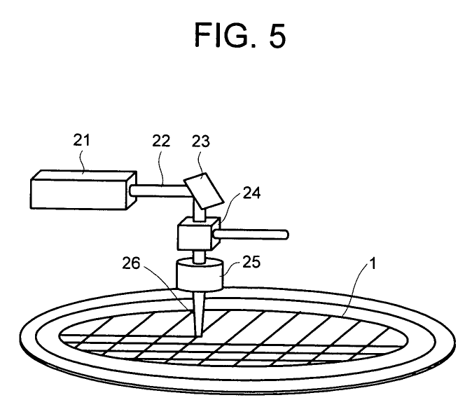

The constitution of a machining part of a laser device used in this embodiment is shown in FIG. 5. A laser oscillator 21 is a pulse oscillator (oscillation frequency: 50 kHz to 200 kHz, pulse width: 10 ns to 400 ns) by a Q switch, and here a wavelength of 355 nm is used. This is selected in consideration of optical machinability by wavelength, power level necessary for machining, and mass production performance as the oscillator. A laser beam 22 irradiated from the laser oscillator 21 passes through several refractive mirrors 23, is controlled to a power necessary for machining by an attenuator 24 near a machining point and finally collected by a condenser lens 25 to be irradiated to the semiconductor wafer 1. A machining diameter of a laser beam 26 collected by the condenser lens 25 is a machining width of about 5 μm to about 30 μm in an uppermost layer of the machining part.

To prevent film peeling, particularly film peeling from inside the laminated film 7 in laser machining in a process of forming the laser-machined trench 20 (laser dicing process), it is important to optimize the irradiation condition of the laser beam. If pulse energy given to a work by the laser beam is decomposed when machining parameters in the laser machining are considered, it is divided into peak power (W) and pulse width (ns) being irradiation time. When the laminated film 7 is machined by irradiating the laser beam thereto, these two machining parameters become important.

When pulse energies of laser beams are the same, the one having a shorter pulse width has a higher peak power. This means that by giving energy at a high power in a short period of time, machining by ablation is accelerated. Conversely, this means that the one having a longer pulse width is machined by heat by giving energy at a lower power in a long period of time. Conventional laser machining is performed mainly by ablation.

As described above, if a film which is difficult to machine by the laser beam is placed on the upper layer side of the laminated film 7, an inside film which is easy to machine causes ablation earlier by the laser beam. As a result, internal explosion occurs to cause the upper-layer side film to peel off. When film machining progresses due to the internal explosion, film peeling becomes liable to occur from inside the laminated film 7 if a film such as the low dielectric constant insulating film 13 having a low film strength and adhesion strength exists.

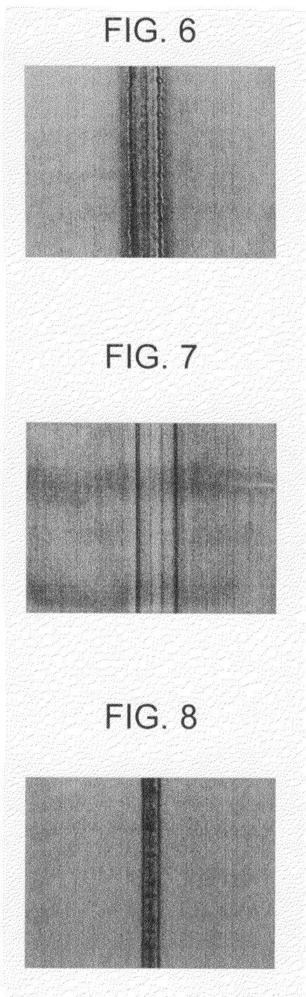

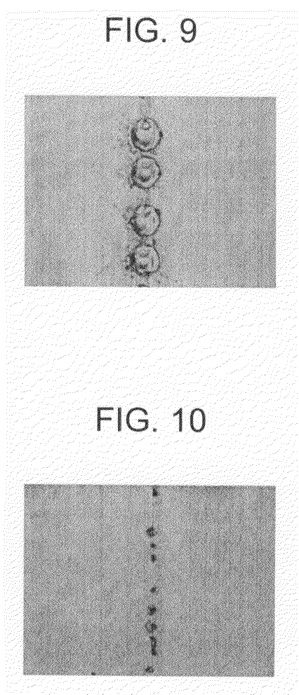

FIG. 6 to FIG. 10 show machinabilities of respective films constituting the laminated film 7 in a single layer state. Here, the laser beam is irradiated to each film (single layer) constituting the laminated film 7 under the same machining condition (pulse energy: 6 μJ, pulse width: 355 ns, 1.0 μm/pulse). FIG. 6 shows the machined state of a SiNₓ film. FIG. 7 shows the machined state of a PAr-based low dielectric constant insulating film (SiLK). FIG. 8 shows the machined state of a SiOC-based low dielectric constant insulating film (BD). FIG. 9 shows the machined state of a TEOS film. FIG. 10 shows the machined state of a FSG film.

As is clear from FIG. 6 to FIG. 10, some films are machined linearly along the laser beam and some films are machined partially although machining is performed under the same laser machining condition. In the film machined partially, the Si substrate as a foundation is also machined. In the laminated film 7 shown in FIG. 4, the low dielectric constant insulating film 13 and the SiNₓ film 18 are easy to machine by the laser beam, whereas a silica (SiOₓ) film such as the TEOS film 14, the FSG film 16, or the like is difficult to machine by the laser beam.

The laminated film 7 formed on the Si substrate 6 generally has an SiOₓ film (the TEOS film 14, the FSG film 16, or the like) as the passivation layer 12 on the upper layer side. The SiOₓ film is difficult to machine by the laser beam, so that when the laser beam is irradiated, the low dielectric constant insulating film 13 existing on the inner side of the laminated film 7 tends to cause ablation earlier. Since the low dielectric constant insulating film 13 has a low film strength and adhesion strength, film peeling becomes liable to occur from inside the laminated film 7 due to the ablation of the inner-layer side low dielectric constant insulating film 13.

In this embodiment, based on a peak energy Y and an irradiation time X per unit irradiation length of the laser beam, the laser beam is irradiated under the condition that the film inside the laminated film 7 does not tend to cause ablation earlier. More specifically, the laser beam is irradiated under the condition that the peak energy Y (W) and the irradiation time X (ns/μm) per unit irradiation length satisfy the following expression (1) to remove part of the laminated film 7 to form the laser-machined trench 20.

Y≦53.3Ln(X)+576 (1)

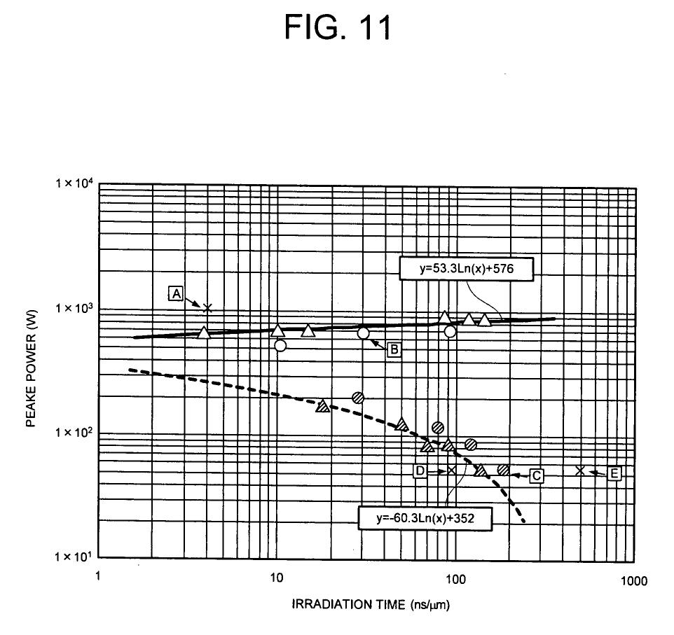

Examples of the machining condition by the laser beam are shown in FIG. 11. The horizontal axis represents the irradiation time X (ns/μm) per unit length of the laser beam, and the vertical axis represents the peak power Y (W) per one pulse of the laser beam. When the value of the peak power Y of the laser beam reaches a region above a line of [53.3Ln(X)+576] (upper line), the peak power Y with respect to the irradiation time X becomes too large, so that the film inside the laminated film 7 becomes liable to cause ablation earlier. Therefore, internal explosion occurs, and film peeling becomes liable to occur from inside the laminated film 7.

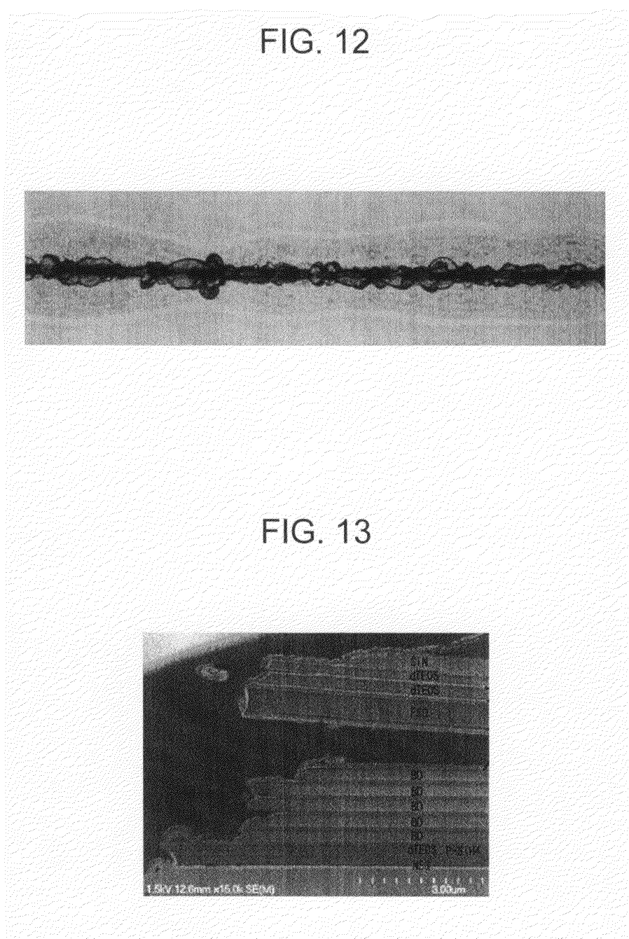

For example, the result of machining under the condition of a point A (peak power Y: 1000 W, irradiation time X: 4 ns/μm) is shown in FIG. 12. It can be seen that film peeling from inside the film occurs along a machining line near the machining line, and locally the upper-layer film peels off greatly. The state of the inside of the laminated film 7 at this time is shown in FIG. 13. It can be seen that the film peeling of the laminated film 7 progresses to the inside between layers. When the irradiation condition of the laser beam is set to the region above the upper line in FIG. 11, the result is that in any case, similarly to the condition of the point A, film peeling from inside the film occurs along the machining line, and locally the upper-layer film peels off greatly.

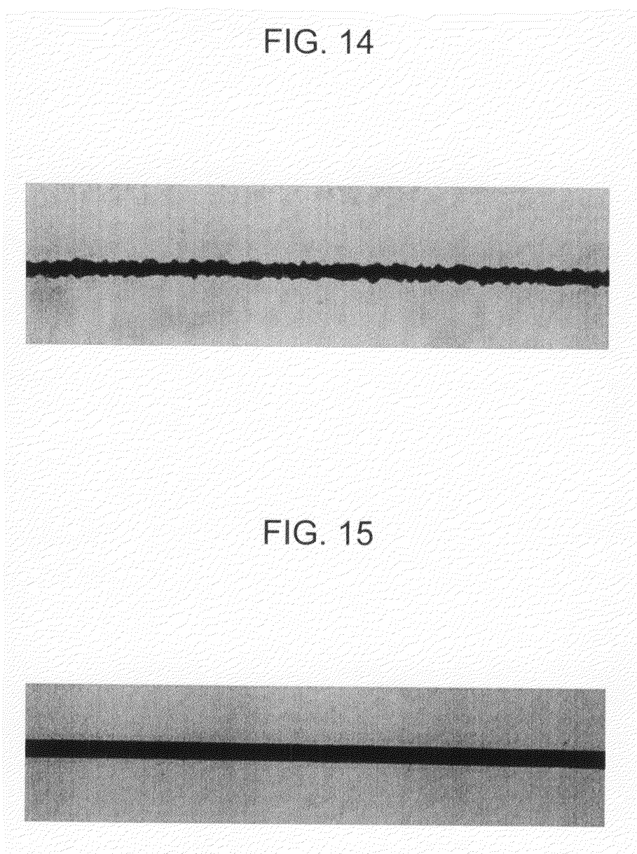

In contrast, the result of machining under the condition of a point B (peak power Y: 700 W, irradiation time X: 30 ns/μm) is shown in FIG. 14. Further, the result of machining under the condition of a point C (peak power Y: 55 W, irradiation time X: 190 ns/μm) is shown in FIG. 15. In FIG. 14 and FIG. 15, it can be seen that such peeling from inside the film along the machining line as shown in FIG. 12 does not occur and laser machining is well performed. This is because machining by heat is mainly performed since the peak power Y is lowered and the irradiation time X is lengthened. Consequently, the internal explosion due to the ablation of the inside film is suppressed, which enables good laser machining of the entire laminated film 7.

The irradiation condition of the laser beam satisfies the condition of expression (1) to suppress the film peeling due to the ablation inside the laminated film 7. Note, however, that if the irradiation time X is too short when the peak power Y of the laser beam is lowered within the condition of expression (1), the machining by heat does not sufficiently progress. Hence, the machining efficiency of the laminated film 7 lowers. More specifically, there is a possibility that machining by the laser beam does not reach the Si substrate 6 and thereby cutting of the laminated film 7 becomes insufficient. It is desirable that the laser beam be irradiated under the condition satisfying the following expression (2) in addition to the condition of expression (1).

Y≦−60.3Ln(X)+352 (2)

By setting the irradiation condition of the laser beam within a region sandwiched between the upper line in FIG. 11 and a line of [−60.3Ln(X)+352] (lower line), it becomes possible to allow the machined trench 20 formed by irradiating the laser beam to certainly reach the Si substrate 6 and cut the laminated film 7 with better reproducibility while suppressing the film peeling due to the ablation inside the laminated film 7. As just described, it is desirable that the laser beam be irradiated under the condition satisfying the following expression (3).

−60.3Ln(X)+352≦Y≦53.3Ln(X)+576 (3)

The point C satisfies the condition of expression (3). In contrast, when the increase of the irradiation time X with respect to the lowering of the peak power Y is insufficient, like the condition of a point D (peak power Y: 55 W, irradiation time X: 95 ns/μm), the machining line is smooth, but the laser-machined trench 20 does not reach the Si substrate 6 and the cut state of the laminated film 7 becomes insufficient. Under such circumstances, the effect of cutting the laminated film 7 including the low dielectric constant insulating film 13 by the laser-machined trench 20 before blade dicing to suppress film peeling and cracking cannot be sufficiently obtained. Accordingly, it is desirable that the irradiation condition of the laser beam be set within the region sandwiched between the upper line and the lower line in FIG. 11.

Further, when FIG. 14 and FIG. 15 are compared, slight irregularities are observe data machining line of the uppermost-layer film in FIG. 14. This is thought because ablation in the inside slightly occurs since the peak power Y is relatively high. When the condition that the peak power Y is relatively high is selected in FIG. 11, the same result as the point B can be obtained. In contrast, according to the condition of the point C that the peak power Y is further lowered and the irradiation time X is lengthened, as is clear from FIG. 15, smoother line machining becomes possible. When the condition that the peak power Y is relatively low is selected in FIG. 11, the same effect as the point C can be obtained.

From the above, it is desirable that the peak power Y of the laser beam be within a range of 20 to 400 W for practical purposes. By setting the peak power Y of the laser beam to 400 W or lower, the machining by heat becomes liable to occur, so that the machining line can be made smoother. However, when the peak power Y of the laser beam becomes lower than 20 W, there is a possibility that the machining efficiency lowers and the laminated film 7 cannot be sufficiently machined even if the irradiation time X is lengthened. As described later, if the irradiation time X is lengthened too much with the lowering of the peak power Y, melting and foaming of the film by heat becomes liable to occur. This also causes degradations in the quality and reliability of the laminated film 7.

It is desirable that the irradiation time X of the laser beam be set within a range of 2 to 400 ns/μm for practical purposes. If the irradiation time X of the laser beam is less than 2 ns/μm, the need for increasing the peak power Y in order to increase the machining efficiency of the laminated film 7, so that the ablation inside the film becomes liable to occur. Further, in order to obtain such smooth line machining as shown in FIG. 15, it is desirable that the irradiation time X of the laser beam be set to 20 ns/μm or more. If the irradiation time X of the laser beam exceeds 400 ns/μm, the melting and foaming of the film by heat becomes liable to occur.

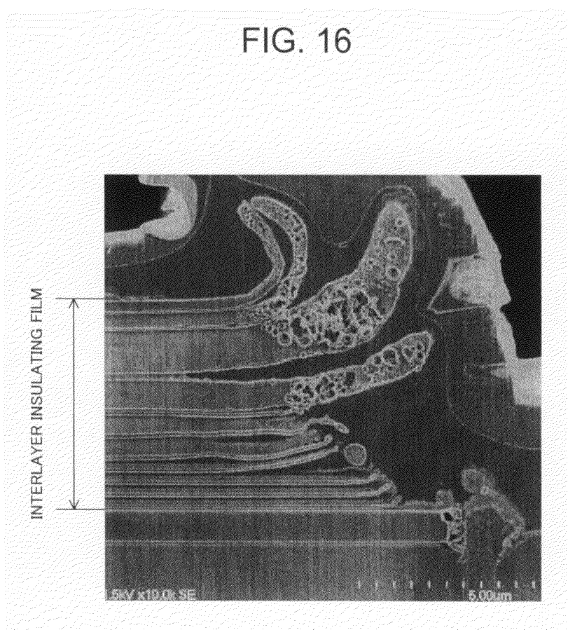

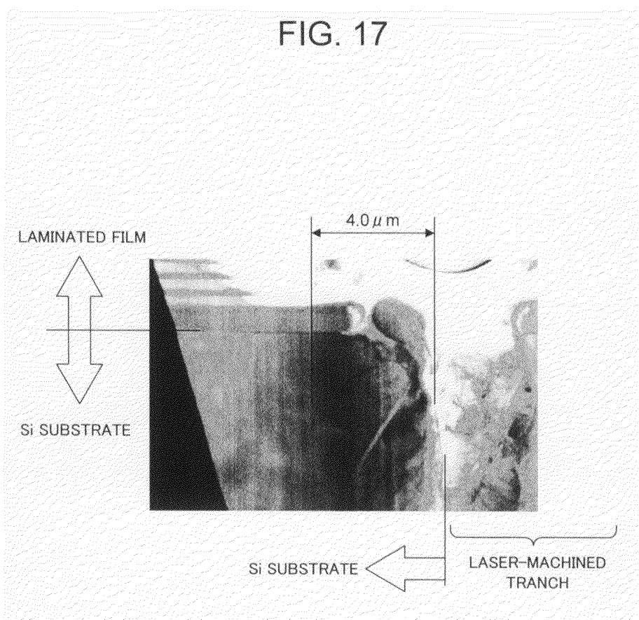

The inside state of the laminated film 7 in the case of machining under the condition of a point E (peak power Y: 55 W, irradiation time X: 500 ns/μm) is shown in FIG. 16. As is clear from FIG. 16, the melting and foaming of the film by heat is observed inside the laminated film 7, and further it can be seen that peeling progresses at film interfaces. As just described, when the heat influence in machining becomes too large, film peeling and damage to the film become liable to occur. Therefore, it is desirable that the irradiation time X of the laser beam be set to 400 ns/μm or less. The result of observation of the heat influence on the Si substrate 6 in laser machining under the condition of the point C by a TEM is shown in FIG. 17. It can be seen that the heat influence on the Si substrate 6 is only about 4 μm.

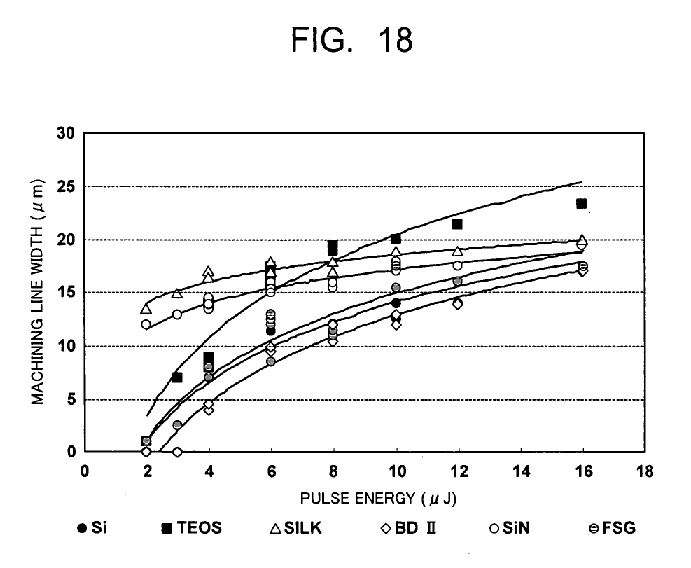

The relations between laser energy and line width of various films are shown in FIG. 18. The horizontal axis represents pulse energy (μJ), and the vertical axis represents machining width by a laser. The change in machining width varies from film to film. This is thought to be caused by a difference in film-specific optical characteristic and machinability by heat generated in machining. It can be said that the SiNₓ film and the PAr-based low dielectric constant film (SiLK) which hardly change between low pulse energy and high pulse energy have high laser machinability. On the other hand, the SiOx film such as the TEOS film or the FSG film the machining width of which changes according to pulse energy has inferior laser machinability. This result indicates that the pulse energy of the laser beam is desirably set to 3 μJ or more in satisfactorily machining various films.

When the laser beam is irradiated along the dicing region 3, the perk energy Y and the irradiation time X per unit irradiation length of the laser beam are set to the condition in the region sandwiched between the upper line of [53.3Ln(X)+576] and the lower line of [−60.3Ln(X)+352] in FIG. 11. This makes it possible to cut the laminated film 7 with good reproducibility and efficiently while suppressing film peeling from inside the laminated film 7. Accordingly, the yield of the cutting process of the laminated film 7 including the low dielectric constant insulating film 13 can be increased, and further it becomes possible to suppress degradations in the quality and reliability of the semiconductor element due to the cutting process of the laminated film 7.

After the above laser dicing process is performed, the semiconductor wafer 1 is cut along the dicing region 3 using a blade. The semiconductor element is fabricated by cutting a portion (central portion of the dicing region 3) corresponding to a region outside the laser-machined trench 20 by a diamond blade to section the element regions 2. Numeral 27 in FIG. 2 denotes a cut portion by the blade. It is desirable that blade machining be performed using a blade having a grain size of #2000 under the condition of a machining speed of 10 to 60 mm/s and a spindle rotation speed of 30 to 50 krpm in order to suppress chipping from the Si substrate 6. By applying the laser machining and the blade machining, it becomes possible to fabricate the semiconductor element 2 of excellent reliability and quality with good yield.

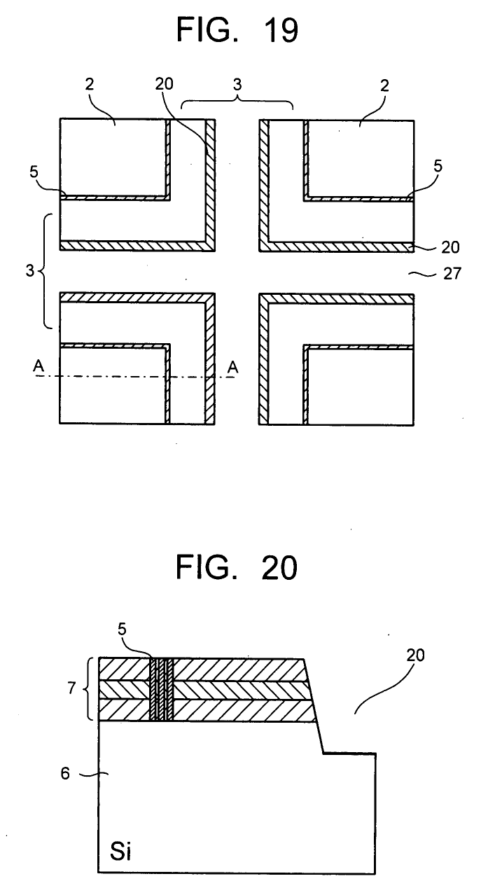

Next, a second embodiment of the present invention will be described with reference to FIG. 19 and FIG. 20. FIG. 19 is a plan view showing a substantial part (corresponding to the region Z surrounded by the square in FIG. 1) of a semiconductor wafer in a magnified form, and FIG. 20 is a sectional view taken along the line A-A in FIG. 19. The constitution of each part of the semiconductor wafer is the same as that in the first embodiment. In the second embodiment, the laser-machined trench 20 is formed near the center of the dicing region 3 outside the element region (active area) 2. Thereafter, blade machining is performed along the laser-machined trench 20 to cut the semiconductor wafer 1 to fabricate the semiconductor element. Consequently, the number of man-hours necessary for laser machining can be reduced. The detailed condition of the laser machining is the same as that in the above first embodiment.

When the blade machining is performed along the laser-machined trench 20 as described above, it is necessary to prevent the laser-machined trench 20 and a cut end portion by the blade from overlapping each other. Compared to the first embodiment, an end portion of the laser-machined trench 20 on the element region (active area) 2 side and the position of a chip end portion formed by the blade machining are closer to each other, so that there is a fear of the influence of machining damage such as chipping by the blade. Hence, it is desirable that the distance between the end portion of the laser-machined trench 20 and the chip end portion be set to at least about 5 μm to about 10 μm.

It is to be understood that the present invention is not intended to be limited to the above embodiments but can be applied to manufacturing methods of semiconductor elements having various structures and manufacturing methods of semiconductor elements having various processes. Such manufacturing methods of semiconductor elements are also included in the present invention. Further, the embodiments of the present invention can be expanded or modified in the scope of the technical idea of the present invention, and the expanded or modified embodiments are also included in the technical scope of the present invention.

What is claimed is:

1. A manufacturing method of a semiconductor element, comprising:
irradiating a laser beam to a semiconductor wafer, which includes plural element regions having a laminated film containing a low dielectric constant insulating film and a dicing region provided to partition off the plural element regions and having the laminated film, along the dicing region to cut at least the low dielectric constant insulating film of the laminated film, the laser beam being irradiated under a condition that a peak energy Y (W) and an irradiation time X (ns/μm) per unit irradiation length of the laser beam satisfy an expression:
Y≦53.3Ln(X)+576; and
fabricating a semiconductor element by cutting the semiconductor wafer along the dicing region to section the plural element regions.

2. The manufacturing method of the semiconductor element according to claim 1,
wherein the irradiation time X per unit irradiation length of the laser beam is adjusted in a range of 2 to 400 ns/μm.

3. The manufacturing method of the semiconductor element according to claim 1,
wherein the laser beam has the perk energy Y in a range of 20 to 400 W.

4. The manufacturing method of the semiconductor element according to claim 1,
wherein the low dielectric constant insulating film has a relative dielectric constant of 3.3 or less.

5. The manufacturing method of the semiconductor element according to claim 1,
wherein the laminated film has a Cu wiring and the low dielectric constant insulating film functioning as an interlayer insulating film of the Cu wiring.

6. The manufacturing method of the semiconductor element according to claim 5,
wherein the laminated film has a silica film placed on an upper side of a laminated portion of the Cu wiring and the low dielectric constant insulating film.

7. The manufacturing method of the semiconductor element according to claim 1,
wherein a trench is formed in a portion of the laminated film irradiated with the laser beam such that the entire laminated film is cut.

8. The manufacturing method of the semiconductor element according to claim 7,
wherein the trench is formed such that a semiconductor substrate located under the laminated film is exposed and a width of an exposed portion of the semiconductor substrate becomes 3 μm or more.

9. The manufacturing method of the semiconductor element according to claim 1,
wherein the element region is surrounded by a chip ring, and the laser beam is irradiated along an outer periphery of the chip ring.

10. The manufacturing method of the semiconductor element according to claim 1,
wherein the semiconductor wafer is cut using a blade.

11. A manufacturing method of a semiconductor element, comprising:
irradiating a laser beam to a semiconductor wafer, which includes plural element regions having a laminated film containing a low dielectric constant insulating film and a dicing region provided to partition off the plural element regions and having the laminated film, along the dicing region to cut at least the low dielectric constant insulating film of the laminated film, the laser beam being irradiated under a condition that a peak energy Y (W) and an irradiation time X (ns/μm) per unit irradiation length of the laser beam satisfy an expression:
−60.3Ln(X)+352≦Y≦53.3Ln(X)+576; and
fabricating a semiconductor element by cutting the semiconductor wafer along the dicing region to section the plural element regions.

12. The manufacturing method of the semiconductor element according to claim 11,
wherein the irradiation time X per unit irradiation length of the laser beam is adjusted in a range of 2 to 400 ns/μm.

13. The manufacturing method of the semiconductor element according to claim 11,
wherein the laser beam has the perk energy Y in a range of 20 to 400 W.

14. The manufacturing method of the semiconductor element according to claim 11,
wherein the low dielectric constant insulating film has a relative dielectric constant of 3.3 or less.

15. The manufacturing method of the semiconductor element according to claim 11,
wherein the laminated film has a Cu wiring and the low dielectric constant insulating film functioning as an interlayer insulating film of the Cu wiring.

16. The manufacturing method of the semiconductor element according to claim 15,
wherein the laminated film has a silica film placed on an upper side of a laminated portion of the Cu wiring and the low dielectric constant insulating film.

17. The manufacturing method of the semiconductor element according to claim 11,
wherein a trench is formed in a portion of the laminated film irradiated with the laser beam such that the entire laminated film is cut.

18. The manufacturing method of the semiconductor element according to claim 17,
wherein the trench is formed such that a semiconductor substrate located under the laminated film is exposed and a width of an exposed portion of the semiconductor substrate becomes 3 μm or more.

19. The manufacturing method of the semiconductor element according to claim 11,
wherein the element region is surrounded by a chip ring, and the laser beam is irradiated along an outer periphery of the chip ring.

20. The manufacturing method of the semiconductor element according to claim 11,
wherein the semiconductor wafer is cut using a blade.
